(19) United States
(12) Patent Application Publication
(10) Pub. No.: US 2011/0265853 A1
(43) Pub. Date: Nov. 3, 2011

(54) DEVICE FOR GENERATING ELECTRICITY

(75) Inventor: Ingo Tjards, Sudbrookmerland (DE)

(73) Assignee: MATRIX GMBH, Worth/Isar (DE)

(21) Appl. No.: 13/113,055

(22) Filed: May 22, 2011

Related U.S. Application Data
(63) Continuation of application No. PCT/DE2009/001641, filed on Nov. 20, 2009.

(30) Foreign Application Priority Data
Nov. 21, 2008 (DE) 10 2008 058 467.3

(51) Int. Cl. H01L 31/052; F21H 1/00; H01L 31/00

(52) U.S. Cl. 136/246; 136/252; 431/100; 136/244

(57) ABSTRACT

The present disclosure relates to a device for generating electricity, having at least one solar panel comprising at least one photovoltaic cell and disposed within view of a light source. The light source is formed from at least one gas-powered lamp wherein a gas flame generated by the lamp is associated with at least one incandescent body comprising at least one transparent bell-shaped member enclosing the gas flame of the lamp forming a closed combustion chamber, characterized in that the bell-shaped member is at least partially enclosed by an at least double-walled glass dome having a vacuum between the dome walls thereof.

### TECHNICAL FIELD

The present disclosure relates to a device for generating electricity, having at least one solar panel comprising at least one photovoltaic cell and disposed within the beam range of at least one light source.

### BACKGROUND

Luminous devices having at least one solar panel comprising a photovoltaic cell disposed within the beam range of a light source are generally known. DE 200 18 328 U1 describes a gas-powered lamp having at least one solar panel in a sealed enclosure and disposed within the beam range of a light source. A gas flame generated by the lamp is associated with at least one incandescent body comprising at least one transparent bell-shaped member enclosing the gas flame of the lamp for forming a closed combustion chamber. The disposal of a solar panel in DE 200 18 328 U1 enables turning the gas lamp on and off without an electrical connection or a battery, and in accordance with the actual light conditions. However, the gas lamp is not designed to produce sizeable quantities of electricity for example as a backup electrical generator within a home.

Known devices for generating electrical energy are photovoltaic systems, which are already widely used to convert into electrical energy some of the radiant energy of the sun penetrating into the Earth's atmosphere. Devices of the type usually have a plurality of solar panels from which a solar panel of relatively large dimensions can be produced. By linking the solar panels and constructing the aforementioned photovoltaic systems there from, corresponding quantities of electrical energy can be generated without the use of fossil fuels, the availability of which is limited.

Besides industrial applications, photovoltaic systems are also increasingly being used in the private sector in order to save fossil fuels, which inter alia are also used for generating electricity, or to provide consumers whose energy requirements are low with a direct supply of electrical energy. The use of photovoltaic systems lends itself especially when camping, as a partially autarchic supply of electrical energy allows a certain mobility. Substantially the only drawback is that it its use is limited to daylight hours and in particular only when there is adequate solar radiation; this renders the desired as an alternative if necessary, or the use of a cost-intensive storage device to store the unused portion in the event of an excess production of electrical energy.

### SUMMARY

A device for generating electricity is disclosed, the device having at least one solar panel comprising at least one photovoltaic cell which is disposed within the beam range of a light source. The device generates electrical energy independently of the time of day and the prevailing sunlight. The device may be used as a backup source of electrical energy.

The invention is embodied by a device having the features of claim 1. Advantageous developments and embodiments of the invention are described in the subordinate claims.

The disclosed device for generating electricity comprises at least one solar panel comprising at least one photovoltaic cell which is disposed within the beam range of a light source. The light source may be at least one lamp operated by gas or a gasified fossil or renewable fuel. A gas flame generated in the lamp is associated with at least one incandescent body and excites the incandescent body to glow. The incandescent body comprises at least one transparent bell-shaped member enclosing the gas flame, thereby forming a closed combustion chamber.

The incandescent body causes the at least one lamp to generate an advantageously high level of its radiated energy as usable radiation. Radiation is usable, if it is within a spectrum that the solar panel can convert into electrical energy, and may for example be visible light. The at last one lamp may be powered by gas, and can generate light independently of the time of day and the prevailing weather conditions. Radiated energy from the lamp is converted into electrical energy by the solar panel disposed within the beam range, i.e. within view, of the lamp. The lamp comprises a burner nozzle, which is preferably directed vertically downward. The gas flame is formed at the end of the burner nozzle. The gas flame is enclosed by the transparent bell-shaped member such that a closed combustion chamber is formed around the gas flame of the lamp. The bell-shaped member is preferably transparent and may be made of a high-temperature ceramic. The bell-shaped member is excited by the gas flame to emit usable radiation. The closed combustion chamber reduces the radiation of heat from the incandescent body, allowing the solar panel to stay relatively cool, thereby increasing their efficiency. The electrical energy from the solar panel may be used to operate low-powered electrical equipment independently of another energy source such as a battery or the electric grid.

The bell-shaped member is partially or completely enclosed by a glass dome which has two or more spatially separated walls. The glass dome may be made of high temperature-resistant glass and be a double-walled design. The enclosed area between the two or more walls of the glass dome is evacuated, so that a partial vacuum exists between the walls of the glass dome. The vacuum between the walls of the glass dome increases the glass dome's heat insulating characteristic and reduces passage of heat through the glass dome. The glass dome hence further reduces the amount of heat transferred from the flame to the solar panels, allowing the solar panels to stay cool, thereby increasing their efficiency. The glass dome has an annular opening, and is placed over the incandescent body formed by the bell-shaped member. The glass dome is rigidly connected to a base of the lamp. The inner wall of the glass dome may be at a uniform distance from the bell-shaped member, but does not contact the bell-shaped member.

An emitter substance can be introduced into and possibly completely fill the area between the bell-shaped member and the glass dome. A preferred emitter substance comprises sodium iodide. Other substances, e.g. rubidium or potassium and their compounds, may be used. Emitter substances may be in a liquid or gaseous state. Sodium iodide emits radiation at a wavelength of about 600 nanometers, the light wavelength lying within the orange range of the visible spectrum. This wavelength is beneficial, as it can be optimally used by solar cells. Other emitter substances, such as rubidium, have an emission spectrum closer to the band gap of silicon, thereby increasing the proportion of usable radiation. However, these other emitter substances are typically more difficult to handle than sodium iodide, which is non-toxic and barely reactive with the environment.

Alternatively, emitter substance may be filled into one or more annular tubes, which are placed partially inside and partially outside the combustion chamber. The annular tubes hence penetrate the bell-shaped member which establishes the out perimeter of the combustion chamber. At least one annular tube is of a design similar to a ring circuit, and is in parts enclosed by the incandescent body which forms the combustion chamber. The at least one annular tube may also penetrate a region of the wall of the bell-shaped member, the region being a hollow cylinder. Each annular tube thus has a tube portion guided along the inner casing surface and the outer casing surface of the bell-shaped member. Each annular tube contains an emitter substance, for example sodium iodide, which is liquefied or gasified depending on the temperature level prevailing inside the bell-shaped member. Each annular tube forms one of a plurality of incandescent bodies.

The gas flame excites the emitter substance to emit radiant energy at a predetermined wavelength. In this arrangement, the emitter substance in the region of the inner casing surface is heated more strongly than the portion outside the bell-shaped member, leading to a self-actuating circulation and to uniform excitation of the emitter substance within an annular tube. Within the heated portion of the annular tube, an absorber-convector unit made of high temperature-resistant ceramic may be provided. The absorber-convector unit comprises a cuboid having vertical boreholes through which the emitter substance rises up and is discharged in the direction of the radiation side. The proportion of emitted radiation is thus further increased.

At least one side of the dome walls is covered with an infrared (IR) reflective coating, which is permissive only to a desired spectrum of the radiation emitting from the gas flame and the incandescent body. Far infrared (heat) radiation is reflected back into the glass dome, thereby causing an even temperature distribution within the combustion chamber. A partial vacuum may be present in the emitter substance space for the purpose of lowering the boiling point.

Provision is also made for supply and waste-gas pipes to be media-conductively connected to the combustion chamber. The pipes are preferably routed through at least one heat exchanger. The supply and waste-gas pipes guided in particular through the base of the lamp are coupled to a heat exchanger with the aid of which an advantageous pre-heating of intake air and of the combustion gases flowing through the supply pipes is ensured. The media to be heated or cooled flow in a counter direction through the heat exchanger.

Furthermore, the waste-gas pipe is connected to a catalyst, which continuously reduces nitrous oxides arising during combustion. According to an advantageous development of the invention, provision is made for a plurality of solar panels to be disposed on at least one arcuate portion around the light source, which modules exhibit a specific arrangement. By means of the plurality of solar panels disposed around the light source, the radiant energy emitted by the light source can be taken up to a large extent or in a relatively large proportion thereof and converted into electrical energy. The solar panels may be disposed around the light source both completely and only on an arcuate portion. In the case of an only partial disposal around the light source, a reflector may be provided in particular on the side of the light-generating gas flame opposite the solar panels, which correspondingly loss-freely reflects the radiation emitted in this region and diverts it in the direction of the solar panels disposed around the light source at a pre-determined angle.

The solar panels preferably form a hollow-cylindrical module body around the light source by means of which module body the ratio of the radiant energy absorbed by the solar panels to the radiant energy emitted by the, for example, gas-powered lamp is further improved. To form the hollow-cylindrical module body, the solar panels may be disposed annularly around the light source, the annularly disposed solar panels being optionally arranged in a plurality of levels above one another depending on the height of the gas flame generated by the lamp.

Provision is also made for each solar panel to be disposed with its radiant energy-absorbing surface approximately perpendicular to the longitudinal axis of the light source formed by the flame. This has the advantage that the radiant energy consequently also impinging approximately perpendicularly on a particular solar panel is only slightly reflected by its surface and a relatively high proportion thereof is converted. In the case of a solar panel manufactured in particular from silicon semiconductor crystals and consistently exhibiting a flat surface, the dimensions and thus the number of solar panels to be positioned around the light source depend on the power of the light source used and the resulting distance between the light source and a particular solar panel. It is also conceivable that, instead of the usually planar solar panel, solar cells or solar panels manufactured from organic components may be used, which solar cells or solar panels exhibit flexible material properties. With the use of cells or modules of this type, individually adapted forms of a module body enclosing the light source are possible.

A diffusion-absorption heat pump may be coupled to the solar panels for the purpose of cooling them, so that the solar panels can be maintained at an advantageously low operating temperature during operation of the device. An expeller, which is a necessary component of the diffusion-absorption heat pump, is positioned within a corresponding, excess heat-emitting portion of the device, with the result that the operating media can be separated from its carrier medium within the expeller. The use of a heat pump of this type has the advantage that the heat pump process is automatically set in motion by temperature and concentration differences, solely by a purposive delivery of heat, for example in the form of heat of combustion, and therefore requires no additional primary energy.

The lamp is at least region-wise directly enclosed by a lens-like optical element, with the aid of which the radiant energy of the lamp, which usually spreads out uniformly in all directions, is refracted by the lens-like optical element and can be purposively deflected in a specific direction. Especially in connection with the preferably hollow-cylindrical module body composed of solar panels, the radiant energy, which does not normally impinge on the surface of the module body formed of solar panels, can be diverted towards the module body. The ratio of the radiation absorbed by the solar panels to the radiation emitted by the light source can thereby be advantageously further improved. The dimensions of the optical element used also depend on the height of the gas flame generated by the lamp and the incandescent body coming to be used on the lamp.

In particular, the optical element may be a Fresnel lens or a concentric Fresnel lens, the design principle of which enables the use of large lenses of short focal length, albeit without the considerable bulk and the associated weight of conventional lenses. By this means a relatively small device mass can be achieved, which advantageously simplifies the handling of the device in particular during mobile use.

The light source may be formed from a plurality of lamps which may be disposed, in particular, on a circular track about a common center. Through the use of a plurality of lamps, the quantity of radiant energy emitted can be increased by an advantageously simple means, due to which a device of this design according to the invention may occasionally be used even for autarchic supply of, for example, a remotely situated building. The number of lamps used to form the light source depends, in particular, on the magnitude of the energy requirement to be met.

The lamps are preferably disposed evenly distributed on the circular track, advantageously yielding an even distribution of the radiation intensity over the whole of the light source-facing inner surface of the hollow-cylindrical module body. An optimal conversion of the radiant energy impinging on the surface of the module body is thus always ensured by means of all available solar panels.

In the specific case of a light source composed of a plurality of lamps, in order to be able to use the radiant energy emitted by the lamps in the center for obtaining electrical energy also, a reflector is disposed within the center of the circularly arranged lamps. With the aid of the reflector, the radiant energy emitted into the center of the light source can advantageously be deflected in the direction of the hollow-cylindrical module body disposed around the light source.

In this arrangement, the reflector is formed from a plurality of hollow mirrors, in each case with concavely domed reflection surfaces, at least one hollow mirror being associated with each of the lamps forming the light source. The use of a hollow mirror represents a possible embodiment of a radiant energy-deflecting reflector which is of a simple design. For this purpose, each hollow mirror has a predetermined curvature, or radius of curvature, which can vary in the direction of the mirror breadth, thus constantly enabling a precise deflection of the radiant energy. Each lamp of the light source is preferably associated with two hollow mirrors, the longitudinal axes of which are in such a way disposed in an offset position relative to the lamp that the radiant energy emitted by the lamp is not reflected in the direction of the lamp but is deflected through between two mutually adjacent lamps and onto the module body.

The following detailed description of the invention is merely exemplary in nature and is not intended to limit the invention or the application and uses of the invention. Furthermore, there is no intention to be bound by any theory presented in the preceding background of the invention or the following detailed description of the invention.

### BRIEF DESCRIPTION OF THE DRAWINGS

Exemplary embodiments of the disclosure are presented in the drawings.

FIG. 1 is a partial cross-sectional view of a device for generating electricity according to the disclosure;

FIG. 2 is a cross sectional view of the devices as in FIG. 1 along the line A-A;

FIG. 3 is a cross sectional view of alternative embodiment of a device for generating electricity utilizing annular tubes;

FIG. 4 is a cross sectional view of the device as in FIG. 3 along the line B-B;

FIG. 5 is a cross sectional view of alternative embodiment of a device for generating electricity;

FIG. 5a is a cross sectional view of the device as in FIG. 5 along the line A-A;

FIG. 5b is a more detailed partial view of the device is in FIG. 5;

FIG. 5c is a cross sectional view of the detail illustrated in FIG. 5b along the line B-B;

FIG. 6 illustrates a device for generating electricity utilizing a parabolic mirror;

FIG. 6a is a detailed view of the device as in FIG. 6;

FIG. 6b is another detailed view of the device as in FIG. 6.

### DETAILED DESCRIPTION

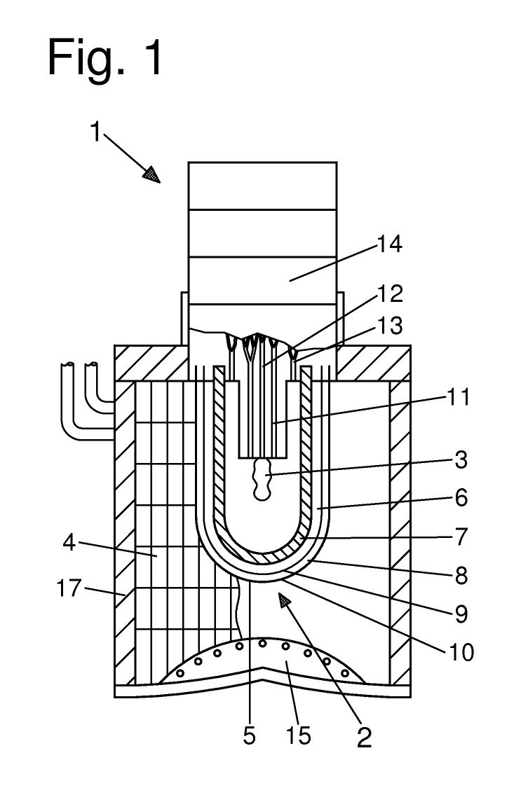

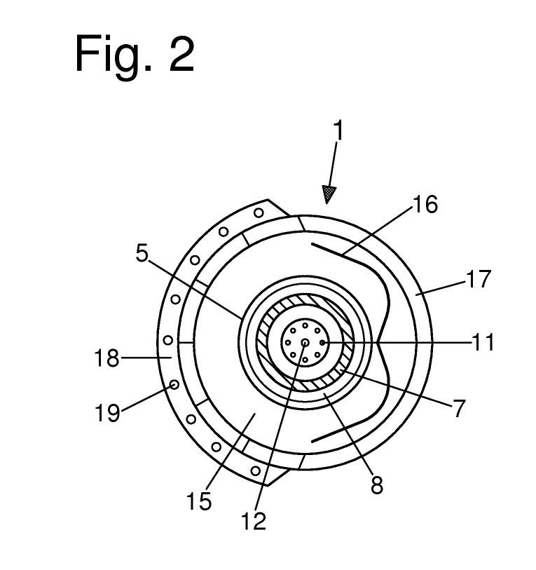

An exemplary device for generating electricity 1 is illustrated with reference to FIG. 1. The device for generating electricity 1 comprises a gas-powered lamp 2, which is located within view of at least one solar panel 4. Solar panel 4 is disposed within the beam range of a gas flame 3 generated by the lamp 2. Lamp 2 further comprises an incandescent body 5 which is incited to glow by gas flame 3 and the chemical reaction taking place during combustion. Incandescent body 5 comprises a bell-shaped member 7 which forms the outer perimeter of a closed combustion chamber 6 that encloses gas flame 3 of lamp 2. Bell-shaped member 7 spatially delimits combustion chamber 6. Bell-shaped member 7 also serves as a heat barrier, retaining heat that is generated by the combustion of gas in flame 3 within combustion chamber 6. Bell-shaped member 7 is preferably transparent. A glass dome 8 is provided which encloses bell-shaped member 7. Glass dome 8 comprises two spatially separated walls, an inner dome wall 9 and an outer dome wall 10. The area between inner dome wall 9 and outer dome wall 10 is evacuated. The particular a vacuum prevailing within glass dome 8 provides glass dome 8 with good thermal insulation characteristics. An emitter substance 43 is disposed between bell-shaped member 7 and glass dome 8. Emitter substance 43, for example sodium iodide, determines the emissions of light from incandescent body 5. Emitter substance 43 preferably exhibits advantageously high radiation intensity within a specific radiation spectrum at which solar panel 4 is effective. An infrared (IR) radiation-reflective coating is preferably applied to the flame-facing sides of both inner dome wall 9 and outer dome wall 10. The IR reflective coating reduces the amount of infrared radiation that escapes combustion chamber 6 through glass dome 8. Flame 3 is fed by gas, which is provided into combustion chamber 6 through a gas supply pipe 12. Fresh air for the combustion of gas is provided through fresh air supply pipes 11 into combustion chamber 6. Waste gas exits combustion chamber 6 through waste gas pipes 13. Gas supply pipe 12, fresh air supply pipes 11 and waste gas pipes 13 are connected to a heat exchanger 14, which transfers heat from hot waste gas leaving combustion chamber 6 through waste gas pipes 13 to air and gas entering combustion chamber 6 through gas supply pipe 12 and fresh air supply pipes 11. One or more reflectors 15 and 16 (reflector 16 is illustrated in FIG. 2) are provided within the device for generating electricity 1, to reflect light from gas lamp 2 towards solar panels 4. Reflectors 15 and 16 can increase yield by directing light that would otherwise be lost onto solar panels 4.

FIG. 2 shows a cross section through the device for generating electricity 1 along the line A-A illustrated in FIG. 1. As is shown, lamp 2 is preferably coaxially disposed at the center of the hollow-cylindrically designed emitter housing 17 of the device for generating electricity 1. The solar panels 4 are disposed in particular so as to be distributed only over a portion of the inside of the emitter housing 17. Furthermore, a reflector 16 in the form of a parabolic chamfered mirror is provided within the emitter housing 17. Reflector 16 reflects light that exits lamp 2 opposite to the location of solar panels 4 back onto solar panels 4. Exemplary light rays are illustrated in FIG. 2. Solar panels 4 are connected to a mounting component 18, through which a plurality of coolant pipes 19 are guided in a predetermined spacing. Coolant pipes 19 may be connected to a diffusion-absorption heat pump (not shown) to keep the solar panels 4 at an advantageously low operating temperature.

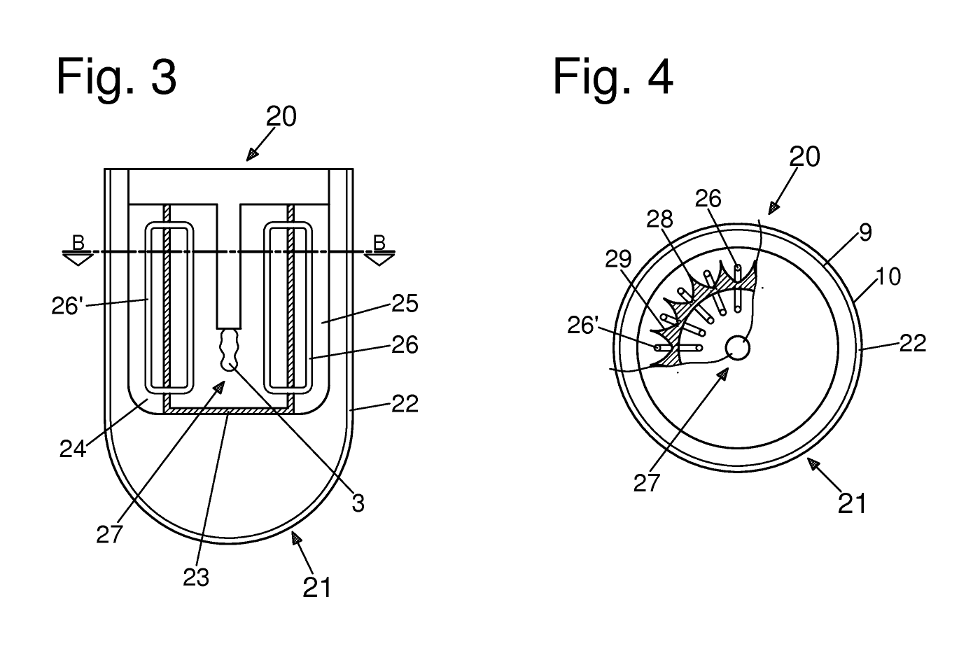

FIG. 3 illustrates another exemplary embodiment of a device for generating electricity 20. Lamp 21 is enclosed by a glass dome 22 which establishes a heat barrier, enclosing in particular radiant heat. Lamp 21 comprises a bell-shaped member 23 which establishes the outer perimeter of the combustion chamber 27. A plurality of ring circuit-like annular tubes 26, 26′ are provided, which are partially located inside the combustion chamber 27 and partially located outside the combustion chamber 27. The annular tubes 26, 26′ penetrate the vertical wall 24 of bell-shaped member 23 and jointly form an incandescent body 25. The annular tubes 26, 26′ are filled with a radiant energy-generating emitter substance. The emitter substance within annular tubes 26, 26′ is incited to emit radiant energy by gas flame 3 burning within combustion chamber 27. During operation, the emitter substance within annular tubes 26, 26′ automatically begins to circulate, due to the temperature difference of the emitter substance in sections of the annular tubes 26 disposed inside combustion chamber 27 and those sections of the annular tubes 26, 26′ disposed outside combustion chamber 27.

FIG. 4 shows a cross section through the device for generating electricity 20 along the line B-B in FIG. 3. The annular tubes 26, 26′ are circumferentially spaced around the center of the lamp 21, which ensures a relatively uniform emission of radiation generated by the emitter substance within annular tubes 26, 26′. On the outside of the bell-shaped member 23, reflectors 28, 29 are disposed, which are preferably formed as parabolic chamfered mirrors and divert or reflect radiation in the direction of the solar panels disposed about the light source.

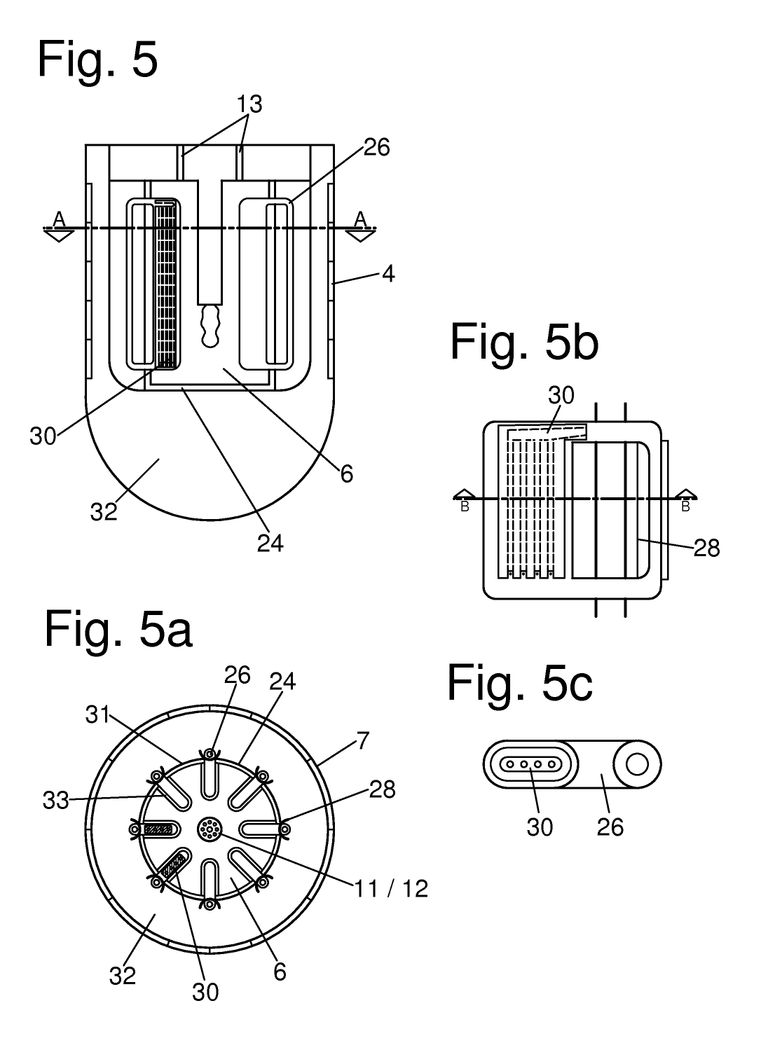

FIG. 5 illustrates another alternative embodiment of a device for generating electricity. An absorber-convector ceramic body 30 is disposed within the annular tubes 26. Annular tubes 26 are made of high temperature-resistant glass. Absorber-convector ceramic body 30 consists of a substantially cuboid insert which is perforated with boreholes. Vertical boreholes are provided, which extend from the bottom of the absorber-convector ceramic body 30 up to an horizontal borehole, which opens towards the side of the absorber-convector ceramic body 30 and which is aligned with the annular tubes 26. Emitter substance within annular tubes 26 can hence flow upward through the vertical boreholes in the absorber-convector ceramic body 30. The emitter substance is then guided sideways to exit the absorber-convector ceramic body 30 and flow through the annular tubes 26 out of the combustion chamber. Sections of the annular tubes 26 located outside the combustion chamber may be referred to as radiation emitting sections. The absorber-convector ceramic body 30 functions to heat and vaporize the emitter substance and transport it into the outer sections of the annular tubes 26. It also serves to absorb energy radiated from the wall of the combustion chamber and thereby transfer heat energy to the emitter substance by conduction.

FIG. 5a is a cross-sectional view of the device shown in FIG. 5 along the line A-A. An inwardly-acting reflector 31 composed of a reflectively coated temperature-resistant material can be seen. The inwardly-acting reflector 31 for the most part encloses the incandescent body and radiates heat energy of the combustion-chamber wall back into the combustion chamber. This helps protect solar panels 4 from adverse radiation and, retains heat energy within the incandescent body, and more particularly at the heat-absorbing sections of the annular tubes 26. The reflector 31 and the parabolic chamfered reflector 28 can be divided into a plurality of segments and be held on the outer annular tubes 26 by suitable clips which are not shown. In this arrangement the reflector 31 does not touch the combustion-chamber wall and is protected by the vacuum 32 from the introduction of heat by convection and heat conduction. The evacuated space 32 serves the same purpose as the Dewar vessel formed in FIG. 1 by double glass dome 8.

With reference to FIG. 5a it is shown that the space formed from the wall of the combustion chamber partially enclosing the inner annular tube portion and from the heat-absorbing annular tubes 26 part of the combustion chamber is advantageously filled with a granulate 33. This has the effect that not only the radiant energy but also energy transferred by heat conduction is directed into the annular tubes 26. The granulate 33 preferably consists of spherical grains of a high-temperature ceramic and can become compacted, contingent upon the preferably at least approximately uniform grain size, not upon thermal expansion and contraction on cooling. The granulate 33 thus remains mobile relative to itself and thus exerts only slight forces on the environment containing it. To prevent trickling out, the granulate 33 preserves a curved projection of the combustion-chamber wall towards the annular tubes 26 (not shown). The curved projections do not touch the annular tubes 26, but are fixed at a distance smaller than the grain size.

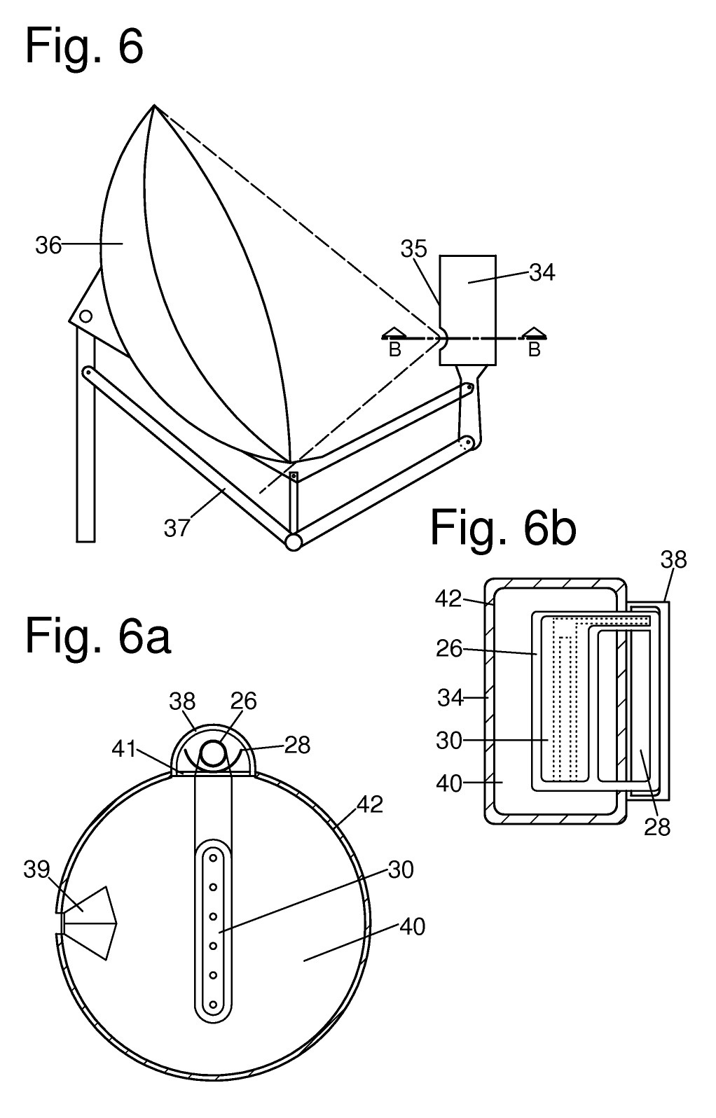

Referring now to FIG. 6, an alternative solar-thermal embodiment of a device for generating electricity is exemplarily illustrated. In this example, solar energy is used to generate a desired beam. In the solar-thermal embodiment, an evacuated vacuum container 34 is reflectively coated from inside. The evacuated vacuum container 34 is preferably cylindrical in shape and provided with a small entry window 35 inside which a high temperature-resistant annular tube 26 is located, which in turn exhibits an absorber-vaporizer unit made of high temperature-resistant ceramic. The solar radiation is focused by a parabolic mirror 36 made of low heat-distortion glass ceramic, known from cool top platforms, and projected through the entry window 35 onto the absorber-vaporiser unit.

The vacuum container 34 shown in FIGS. 6, 6a and 6b serves to accommodate the annular tube 26 in order to transfer heat energy into the annular tube 26 and preserve from heat losses, even in this solar-thermal variant of the device.

A corner reflector 39 is mounted on the side of the entry window 35 located within the vacuum container 34, the corner reflector 39 deflecting the incoming rays in the direction of the absorber-convector unit.

The internal walls 42 of the vacuum container 34 accommodating the annular tube 26 are similarly reflectively coated, advantageously with corner reflectors having angular surfaces 42 positioned at right angles to one another, in order to project the thermal radiation of the absorber back onto the absorber. Since only the absorber-convector unit and the emitter substance radiate, but not the glass of the annular tube, the energy advantageously remains contained inside the container in the emitter substance, and can therefore for the most part only leave the system on the side of the annular tube 26 emitting the radiation. On one side the annular tube 26 penetrates with its radiation-emitting side the vacuum container 34, but is also to be found in the vacuum via a glass dome 38. Similarly, this opening is also reflectively coated towards the inside via a separating wall 41—penetrated only by the tubing of the annular tubes 26. In the vacuum container 34 there may also be a duct for heating a heat-conveying medium for the purpose of obtaining thermal energy. The separating wall 41 consists of at least two parts which are incorporated so as to overlap and are fixed to the vacuum container 34.

The entry window 35 consists of antireflective glass which, withstanding the external pressure, is fixed to the vacuum container 34 and may also be convex towards the inside. The focus of the parabolic mirror 36 lies within this convexity.

The parabolic mirror 36 consisting of low heat-distortion glass ceramic can be made to track the position of the sun and offers the advantage of defining the focus precisely, thereby being able to keep the entry window to a small size. By this means heat loss due to radiation can be kept at a low level.

The parabolic mirror 36 may be chamfered, circular or ellipsoid in shape. In the chamfered embodiment, the entry window 35 is designed as a longitudinal opening.

The vacuum container 34 is advantageously movably mounted, and while the parabolic mirror 36 is tracking the position of the sun, is held constantly in an approximately vertical position by an adjusting rod linkage. The adjusting rod linkage 37 is connected to the parabolic mirror by a mechanism.

The dish-like glass dome 38 made of antireflective glass allows the desired radiation to exit and is fixed to the vacuum container 34 so as to be airtight. In front thereof, a solar panel (not shown) is attached on the outside and generates electrical energy.

The corner reflector 39 located on the inside has an opening in its angle, which is formed from the three mirror surfaces and are at right angles to one another, into which opening the entry window 35 concavely bulges. The reflective surfaces extend inwardly as far as the absorber, though not as far as the annular tube 26.

The vacuum 40 prevailing within the vacuum container 34 prevents heat losses.

While the present invention has been described with reference to exemplary embodiments, it will be readily apparent to those skilled in the art that the invention is not limited to the disclosed or illustrated embodiments but, on the contrary, is intended to cover numerous other modifications, substitutions, variations and broad equivalent arrangements that are included within the spirit and scope of the following claims.

What is claimed is:

1. A device for generating electricity comprising:
a light source, and
at least one solar panel comprising at least one photovoltaic cell configured to generate electricity and disposed within view of the light source,
wherein the light source comprises one or more gas lamps providing a gas flame which is fed by a gas or a gasified fossil or renewable fuel, the flame being associated with at least one incandescent body, and
wherein the at least one incandescent body comprises
a bell-shaped member enclosing the gas flame and forming a closed combustion chamber, and
a glass dome which least partially encloses the bell-shaped member and which comprises two or more spatially separated walls having an enclosed area between them, the enclosed area between the two or more walls being at least partially evacuated.

2. The device as in claim 1, further comprising an emitter substance disposed between the bell-shaped member and the glass dome, the emitter substance being able to generate light.

3. The device as in claim 1, further comprising at least one annular tube filled with an emitter substance, wherein the annular tube is partially located inside the bell-shaped member and partially located outside the bell-shaped member, penetrating the bell-shaped member in at least one region.

4. The device as in claim 1, further comprising an infrared reflecting coating provide on at least one side of at least one of the two or more walls of the glass dome.

5. The device as in claim 1, further comprising:
a gas supply pipe;
a fresh air supply pipe;
a waste gas pipe; and
a heat exchanger,
wherein the gas supply pipe, the fresh air supply pipe and the waste gas pipe are media-conductively connected to the combustion chamber, and are located at least partially within the heat exchanger.

6. The device as in claim 5, further comprising a catalyst operatively connected to the waste gas pipe.

7. The device as in claim 1, comprising a plurality of solar panels disposed on at least one arcuate portion around the lamp.

8. The device as in claim 1, comprising a plurality of solar panels disposed to form a cylindrical body around the lamp.

9. The device as in claim 1, wherein the flame establishes a longitudinal axis of the lamp, and the at least one solar panel is aligned with its surface approximately perpendicular to the longitudinal axis of the lamp formed by the gas flame.

10. The device as in claim 1, further comprising a diffusion-absorption heat pump coupled to the at least one solar panel and configured to cool the at least one solar panel.

11. The device as in claim 1, further comprising an optical element which at least partially encloses the lamp.

12. The device as in claim 11, wherein the optical element is a Fresnel lens.

13. The device as in claim 1, wherein the light source comprises a plurality of gas lamps which are disposed on a circular track about a common center.

14. The device as in claim 13, wherein the gas lamps are evenly distributed on the circular track.

15. The device as in claim 13, further comprising a reflector which is disposed within the common center.

16. The device as in claim 15, wherein the reflector comprises a plurality of hollow mirrors each having concavely domed reflective surfaces, at least one hollow mirror being associated with each of the lamps forming the light source.

17. The device as in claim 3, further comprising an absorber-convector ceramic body disposed within the annular tube, the absorber-convector ceramic body comprising a substantially cuboid insert perforated with boreholes.

18. The device as in claim 1, further comprising an inwardly-acting reflector composed of a reflectively coated temperature-resistant material and located to at least partially enclose the incandescent body thereby reflecting heat energy emanating from the closed combustion chamber back into the closed combustion chamber.

19. The device as in claim 18, further comprising a parabolic chamfered reflector, wherein the inwardly-acting reflector and the parabolic chamfered reflector are composed of a plurality of segments.

20. The device as in claim 3, wherein a space exists between a wall of the combustion chamber and an inner, heat-absorbing, section of the at least one annular tube, and wherein the space is filled with a granulate.

21. The device as in claim 20, wherein the granulate consists of spherical grains of a high-temperature ceramic.

22. The device as in claim 20, further comprising curved projections on the wall of the combustion chamber towards the at least one annular tube, wherein the curved projections are fixed at a distance smaller than a grain size of the granulate.

23. The device as in claim 3, further comprising:
a vacuum container enclosing the device, the vacuum container having an entry window;
an absorber-vaporizer unit made of high temperature-resistant ceramic that operatively connected to the at least one annular tube; and
a parabolic mirror made of low heat-distortion glass ceramic, the parabolic mirror being configured to project solar radiation through the entry window onto the absorber-vaporizer unit.

24. The device as in claim 23, further comprising a corner reflector at the entry window inside the vacuum container, configured to deflecting incoming solar radiation towards the absorber-vaporizer unit.

25. The device as in claim 23, wherein internal walls of the vacuum container are reflectively coated and configured to reflect thermal radiation from the absorber-vaporizer unit back onto the absorber-vaporizer unit.

26. The device as in claim 23, further comprising a separating wall which is reflectively coated towards the inside.

27. The device as in claim 23, wherein the parabolic mirror is adjustable to track the position of the sun.

28. The device as in claim 27, wherein the vacuum container is movably mounted, and while the parabolic mirror is tracking the position of the sun, is held in an approximately vertical position by an adjusting rod linkage.
